(19) United States
(12) Patent Application Publication
(10) Pub. No.: US 2009/0251981 A1
(43) Pub. Date: Oct. 8, 2009

(54) MEMORY WITH A FAST STABLE SENSING AMPLIFIER

(76) Inventors: Po-Hao Huang, Taichung City (TW); Hong-Yi Liao, Yun-Lin Hsien (TW)

Correspondence Address: NORTH AMERICA INTELLECTUAL PROPERTY CORPORATION, P.O. BOX 506, MERRIFIELD, VA, 22116, US

(21) Appl. No.: 12/099,776

(22) Filed: Apr. 8, 2008

(51) Int. Cl. G11C 7/00

(52) U.S. Cl. 365/205; 365/207

(57) ABSTRACT

A memory includes a memory cell, a sensing amplifier, four N-type MOS transistors, a reference circuit, and a comparator. The sensing amplifier is used for sensing digital data stored in the memory cell of the memory and generating an output signal corresponding to the digital data when the memory cell is read. The sensing amplifier includes a current source, a voltage generator, an auxiliary transistor, and an operational amplifier. The auxiliary transistor is coupled in parallel to the current source so as to provide an additional current to the sensing amplifier initially. Thus, the sensing amplifier can output a stable signal in a short time so as to improve the performance of the memory.

### BACKGROUND OF THE INVENTION

1. Field of the Invention

The prevent invention relates to a memory, and more particularly, to a memory with a fast stable sensing amplifier.

2. Description of the Prior Art

A memory is an important component in electronic products. The memory includes a memory cell array including memory units each for storing a bit of digital data and performing programming, erasing, and reading according to control signals transmitted from a word line, a bit line, etc. A sense amplifier in a memory unit is usually provided for sensing digital data stored in a memory cell of the memory unit and generating an output signal corresponding to the digital data when the digital data is read from the memory cell.

Please refer to FIG. 1. FIG. 1 is a circuit diagram of a memory 10 according to the prior art. The memory 10 comprises a memory cell 12, a sensing amplifier 14, four N-type MOS transistors M1, M2, M3 and M4, a reference circuit 16, and a comparator 18. The transistor M1 is a sensing load. The drain of the transistor M1 is coupled to the memory cell 12. The gate of the transistor M1 is coupled to the output of the sensing amplifier 14. When reading data stored in the memory cell 12, the driving current Icell outputted from the memory cell 12 is injected into the transistor M1 through the node N1, and the transistor M1 generates a sensing voltage V1 at the node N1. The reference circuit 16 provides a reference current Iref to the node N2. The transistor M2 functions as a reference load. The drain of the transistor M2 is coupled to the node N2 and the gate of the transistor M2 is coupled to the node N3. After receiving the reference current Iref, the transistor M2 generates a reference voltage V2 at the node N2. The comparator 18 is used to compare the sensing voltage V1 with the reference voltage V2, and generates an output signal according to the comparison result. The sensing amplifier 14 comprises a current source 22, a voltage generator 24, two P-type MOS transistors M5 and M6, and three N-type MOS transistors M7, M8 and M9. The transistors M5 and M6 are a differential input pair of the sensing amplifier 14. The transistors M7 and M8 are active loads of the sensing amplifier 14. The current source 22 is used for biasing the differential input pair. The voltage generator 24 generates a constant voltage Vref. The sensing amplifier 14 has two input ends coupled to the node N1 and the voltage generator 24 respectively. The output end of the sensing amplifier 14 is coupled to the node N3 for controlling the gate bias voltages of the transistors M1 and M2.

Please refer to FIG. 2. FIG. 2 is a waveform of signals of the memory in FIG. 1. The signal ENRD controls the memory cell 12 to be read. The signal EQ and the signal EQB are complementary signals for controlling a transmission gate 26 coupled between the node N1 and the node N2. The control signal ISO is the output voltage of the sensing amplifier 14 at the node N3. When the signal ENRD turns on the transistor M3, M4, and M9, the driving current Icell of the memory cell 12 outputs to the transistor M1, and the transistor M1 generates the sensing voltage V1 at the node N1. According to the voltage difference between the sensing voltage V1 and the constant voltage Vref, the control signal ISO can feedback to drive the transistors M1 and M2, which results in the sensing voltage V1 at the node N1 in accordance with the constant voltage Vref generated by the voltage generator 24. In other words, the sensing amplifier 14 keeps the sensing voltage V1 substantially equivalent to the constant voltage Vref at the node N1 in the way for driving the transistor M1. When the signal ENRD rises to a high level, the transmission gate 26 is turned on so as to equalize the voltages of the node N1 and the node N2 initially. After the transmission gate 26 is turned off, the sensing amplifier 14 requires a period called “ISO stable time” for outputting a stable level. Since the reference circuit 16 provides the constant reference current Iref to the node N2, the sensing amplifier 14 adjusts the control signal ISO at the node N3 so as to keep the voltage V1 at the node N1 equivalent to the voltage Vref. The transistor M2 mirrors the driving current Icell from the transistor M1. Thus, the comparator 18 equivalently recognizes the driving current outputted from the memory cell 12.

### SUMMARY OF THE INVENTION

According to an embodiment of the present invention, a memory comprising: a memory cell for storing data and outputting a driving current according to the data; a sensing load for receiving the driving current and outputting a sensing voltage; a sensing amplifier for keeping the sensing voltage and generating a control signal, comprising: a current source; and an auxiliary transistor coupled in parallel to the current source for providing an additional current so as to stabilize the control signal in a short time; a reference load for outputting a reference voltage according to the control signal; and a comparator for determining the data stored in the memory cell according to the sensing voltage and the reference voltage.

According to another embodiment of the present invention, a sensing amplifier comprising: an operational amplifier for outputting a control signal; a voltage generator coupled to the operational amplifier for providing a constant voltage; a current source for biasing the operational amplifier; and an auxiliary transistor coupled in parallel to the current source for providing an additional current so as to stabilize the control signal in a short time.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of a memory according to the prior art.

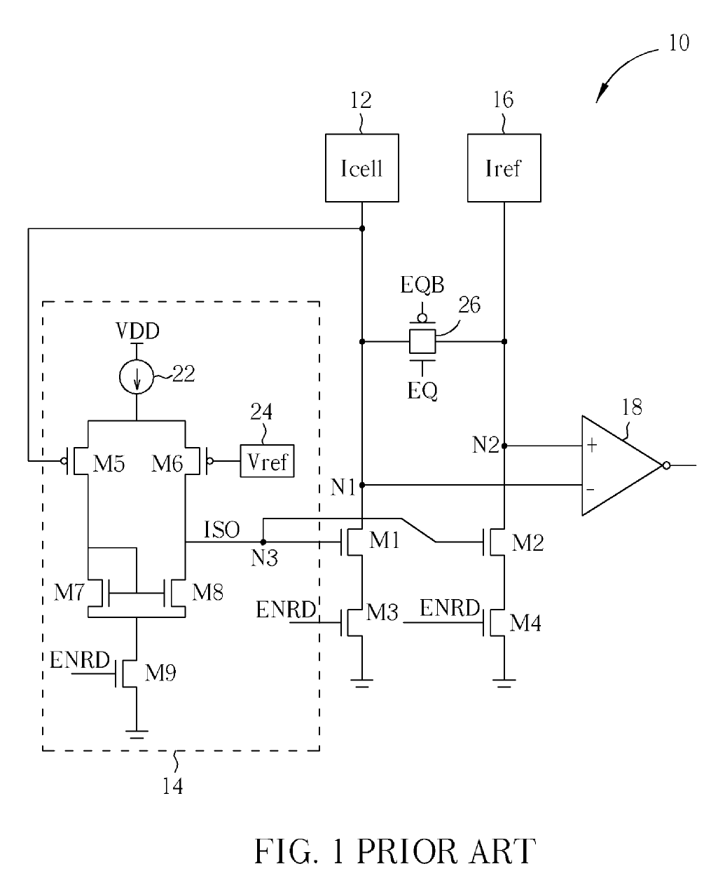

FIG. 2 is a waveform of signals of the memory in FIG. 1.

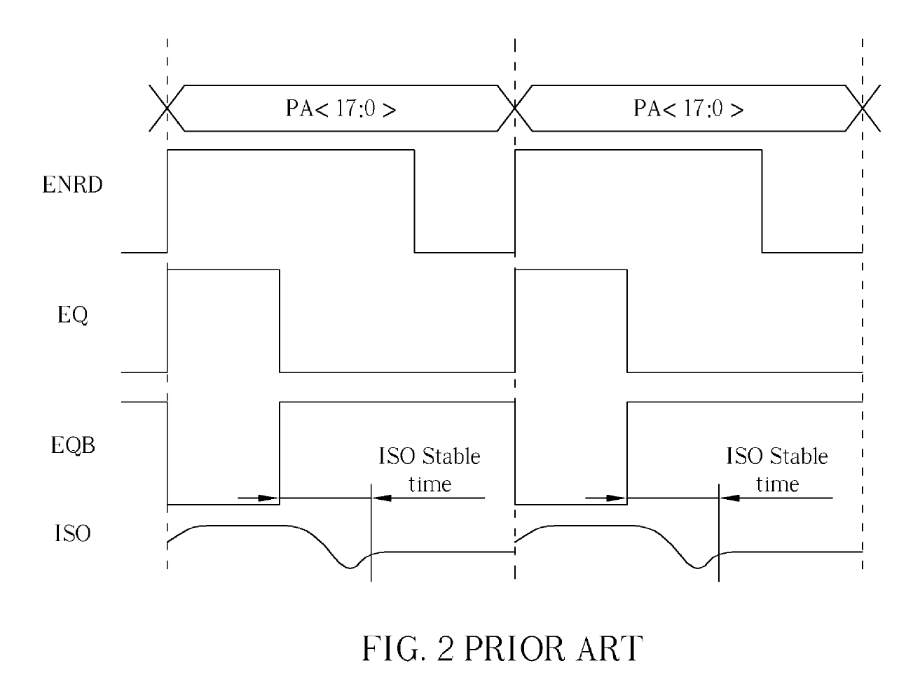

FIG. 3 is a circuit diagram of a first embodiment of a memory according to the present invention.

FIG. 4 is a waveform of signals of the memory in FIG. 3.

FIG. 5 is a circuit diagram of a second embodiment of a memory according to the present invention.

FIG. 6 is a circuit diagram of a third embodiment of a memory according to the present invention.

### DETAILED DESCRIPTION

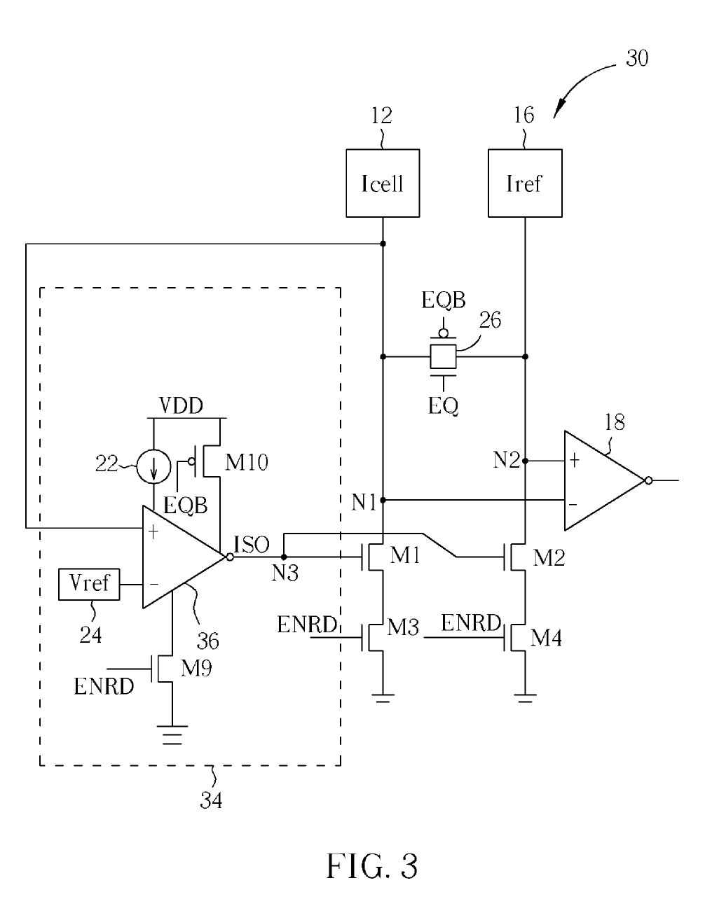

Please refer to FIG. 3. FIG. 3 is a circuit diagram of a first embodiment of a memory 30 according to the present invention. For simplicity, the identical labeled components of the memory 30 and of the memory 10 have the same function. The memory 30 comprises a memory cell 12, a sensing amplifier 34, four N-type MOS transistors M1, M2, M3 and M4, a reference circuit 16, and a comparator 18. The transistor M1 is a sensing load. The drain of the transistor M1 is coupled to the memory cell 12. The gate of the transistor M1 is coupled to the output of the sensing amplifier 34. When reading data stored in the memory cell 12, the driving current Icell outputted from the memory cell 12 is injected into the transistor M1 through the node N1, and the transistor M1 generates a sensing voltage V1 at the node N1. The reference circuit 16 provides a reference current Iref to the node N2. The transistor M2 functions as a reference load. The drain of the transistor M2 is coupled to the node N2 and the gate of the transistor M2 is coupled to the node N3. After receiving the reference current Iref, the transistor M2 generates a reference voltage V2 at the node N2. The comparator 18 is used for comparing the sensing voltage V1 with the reference voltage V2, and generates an output signal according to the comparison result. The sensing amplifier 34 comprises a current source 22, a voltage generator 24, an operational amplifier 36, a N-type MOS transistor M9, and an auxiliary transistor M10. The current source 22 is used for biasing the differential input pair. The auxiliary transistor M10 is coupled in parallel to the current source 22 for providing an additional current for the sensing amplifier 34 initially so that the sensing amplifier 34 can output a stable signal in a short time. The voltage generator 24 generates a constant voltage Vref. The sensing amplifier 34 has two input ends coupled to the node N1 and the voltage generator 24 respectively. The output end of the sensing amplifier 34 is coupled to the node N3 for controlling the gate bias voltages of the transistors M1 and M2.

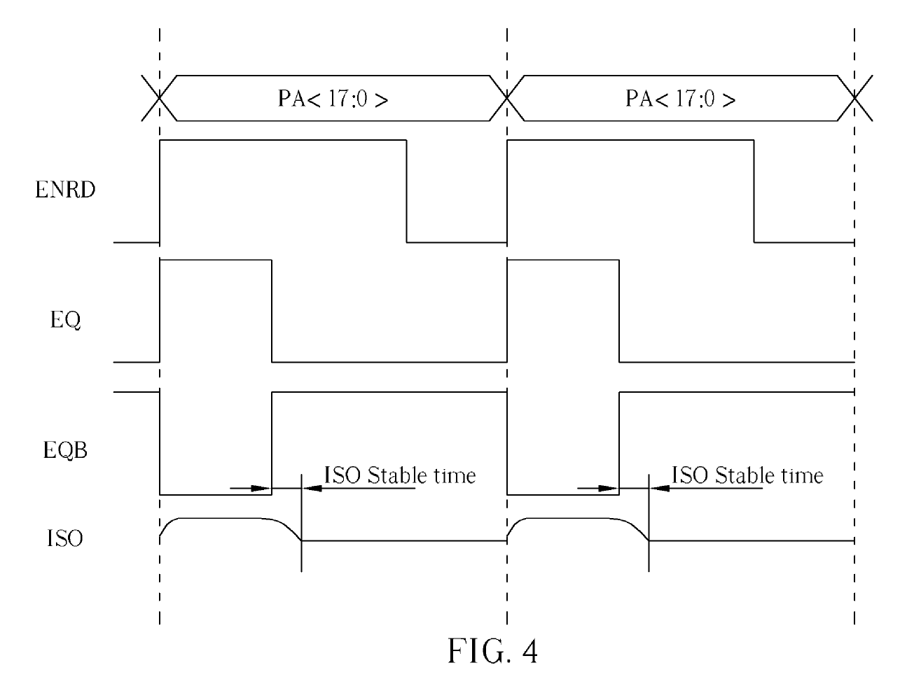

Please refer to FIG. 4. FIG. 4 is a waveform of signals of the memory in FIG. 3. The signal ENRD controls the memory cell 12 to be read. The signal EQ and the signal EQB are complementary signals for controlling a transmission gate 26 coupled between the node N1 and the node N2. Further, the signal EQB is used to control the transistor M10. That is, when the transmission gate 26 is turned on, the transistor M10 is turned on. When the transmission gate 26 is turned off, the transistor M10 is turned off. The control signal ISO is the output voltage of the sensing amplifier 34 at the node N3. When the signal ENRD turns on the transistor M3, M4, and M9, the driving current Icell of the memory cell 12 outputs to the transistor M1, and the transistor M1 generates the sensing voltage V1 at the node N1. According to the voltage difference between the sensing voltage V1 and the constant voltage Vref, the control signal ISO can feedback to drive the transistors M1 and M2, which results in the sensing voltage V1 at the node N1 in accordance with the constant voltage Vref generated by the voltage generator 24. In other words, the sensing amplifier 34 keeps the sensing voltage V1 substantially equivalent to the constant voltage Vref at the node N1 for driving the transistor M1. When the signal ENRD rises to a high level, the transmission gate 26 is turned on so as to equalize the voltages of the node N1 and the node N2 initially. After the transmission gate 26 is turned off, the sensing amplifier 34 requires a period called “ISO stable time” for outputting a stable level. During the period while the transmission gate 26 is turned on, the transistor M10 is turned on to provide an additional current to the sensing amplifier 34, so that the sensing amplifier 34 can stabilize the signal ISO in a short time. For reducing the active current consumption when reading the data of the memory cell 12, the signal ENRD will change to a low level after accurate data is reached. When the signal ENRD rises to the high level, it will take a long time to make the control signal ISO stable. Thus, the transistor M10 can provide an adequate current to accelerate the control signal ISO stable. Since the reference circuit 16 provides the constant reference current Iref to the node N2, the sensing amplifier 34 adjusts the control signal ISO at the node N3 so as to keep the voltage V1 at the node N1 equivalent to the voltage Vref. The transistor M2 mirrors the driving current Icell from the transistor M1. Thus, the comparator 18 equivalently recognizes the driving current outputted from the memory cell. The short ISO stable time means the fast speed of the sensing amplifier 34. The sensing amplifier 34 according to the present invention comprises the transistor M10 coupled in parallel to the current source 22 so as to reduce the ISO stable time. The transistor M10 is turned on during the period while the transmission gate 26 is turned on, so an additional current is provided to the sensing amplifier 34 during this period. Thus, the sensing amplifier 34 can reduce the ISO stable time.

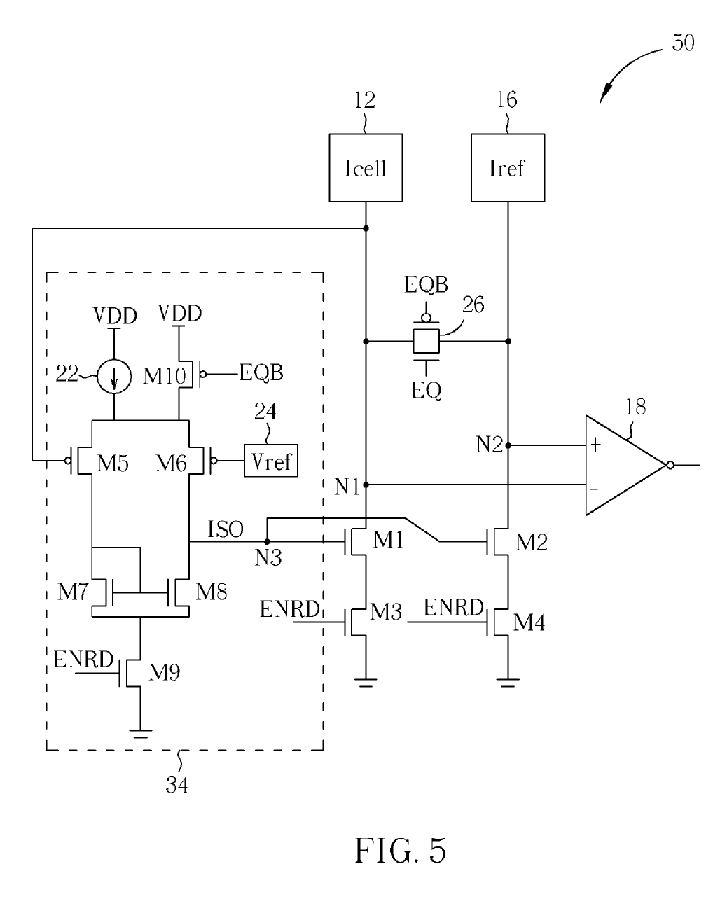

Please refer to FIG. 5. FIG. 5 is a circuit diagram of a second embodiment of a memory 50 according to the present invention. In the second embodiment, the operational amplifier 36 in FIG. 3 is implemented with two P-type MOS transistors M5 and M6, and two N-type MOS transistors M7 and M8. The transistors M5 and M6 are a differential input pair of the sensing amplifier 34. The transistors M7 and M8 are active loads of the sensing amplifier 34. The auxiliary transistor M10 is a P-type MOS transistor. The auxiliary transistor M10 is coupled in parallel to the current source 22 and controlled by the signal EQB so as to provide an additional current to the sensing amplifier 34 initially.

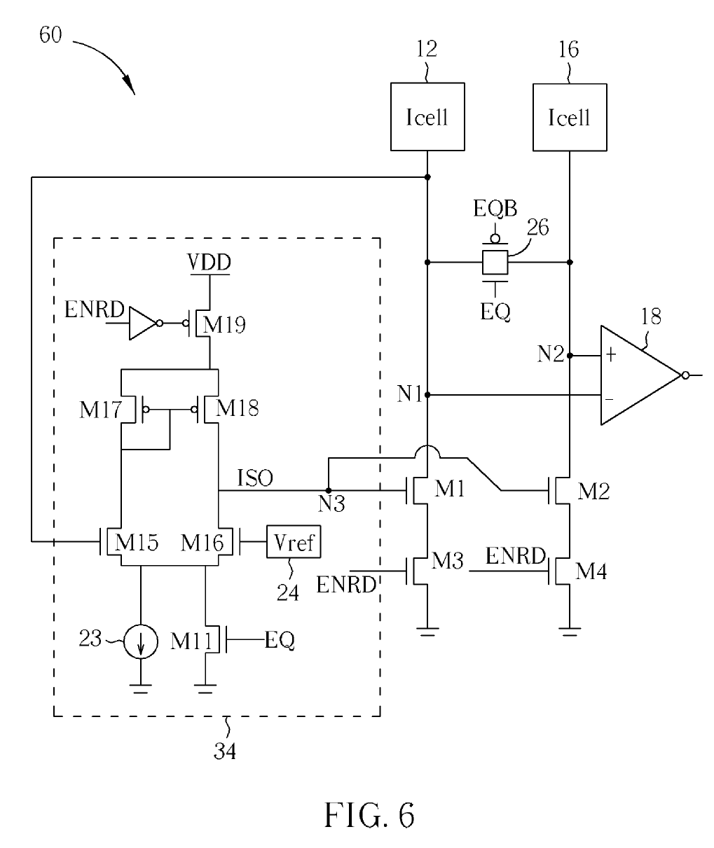

Please refer to FIG. 6. FIG. 6 is a circuit diagram of a third embodiment of a memory 60 according to the present invention. In the third embodiment, the sensing amplifier 34 comprises a current source 23, an auxiliary transistor M11, two N-type MOS transistors M15 and M16, and two P-type MOS transistors M17 and M18, and a P-type MOS transistor M19. The transistors M15 and M16 are a differential input pair of the sensing amplifier 34. The transistors M17 and M18 are active loads of the sensing amplifier 34. The signal ENRD turns on the transistor M19 through an inverter. The auxiliary transistor M11 is a N-type MOS transistor. The auxiliary transistor M11 is coupled in parallel to the current source 23 and controlled by the signal EQ so as to provide an additional current to the sensing amplifier 34 initially.

In conclusion, a memory according to the present invention comprises a memory cell, a sensing amplifier, four N-type MOS transistors, a reference circuit, and a comparator. The sensing amplifier is used to sense digital data stored in the memory cell of the memory and generate an output signal corresponding to the digital data when the memory cell is read. The sensing amplifier according to the present invention can output a stable signal in a short time so as to improve the performance of the memory. The sensing amplifier comprises a current source, a voltage generator, an auxiliary transistor, and an operational amplifier. The auxiliary transistor is coupled in parallel to the current source so as to provide an additional current to the sensing amplifier initially so that a stable level output can be reached in a short time. Thus, the performance of the sensing amplifier is improved.

Those skilled in the art will readily observe that numerous modifications and alterations of the device and method may be made while retaining the teachings of the invention.

What is claimed is:

1. A memory comprising:
a memory cell for storing data and outputting a driving current according to the data;
a sensing load for receiving the driving current and outputting a sensing voltage;
a sensing amplifier for keeping the sensing voltage and generating a control signal, comprising:
a current source; and
an auxiliary transistor coupled in parallel to the current source for providing an additional current so as to stabilize the control signal in a short time;
a reference load for outputting a reference voltage according to the control signal; and
a comparator for determining the data stored in the memory cell according to the sensing voltage and the reference voltage.

2. The memory of claim 1, further comprising a transmission gate coupled between the sensing load and the reference load.

3. The memory of claim 2, wherein the auxiliary transistor is turned on when the transmission is turned on, and the auxiliary transistor is turned off when the transmission is turned off.

4. The memory of claim 1, further comprising three transistors coupled to the sensing amplifier, the sensing load, and the reference load respectively for controlling the memory cell to be read.

5. The memory of claim 1, wherein the sensing amplifier further comprising:
two transistors forming a differential input pair;
two transistors coupled to the differential input pair for forming active loads; and
a voltage generator coupled to one of the two transistors of the differential input pair for providing a constant voltage to the differential input pair;
wherein the current source is coupled to the differential input pair for biasing the differential input pair.

6. The memory of claim 5, wherein the sensing amplifier keeps the sensing voltage in accordance with the constant voltage.

7. The memory of claim 1, further comprising a reference circuit coupled to the reference load for providing a constant current.

8. The memory of claim 7, wherein the reference load is an N-type MOS transistor, a drain of the transistor being coupled to the reference circuit, a gate of the transistor being coupled to the sensing amplifier.

9. The memory of claim 1, wherein the sensing load is an N-type MOS transistor, a drain of the transistor being coupled to the memory cell, a gate of the transistor being coupled to the sensing amplifier.

10. A sensing amplifier comprising:
an operational amplifier for outputting a control signal;
a voltage generator coupled to the operational amplifier for providing a constant voltage;
a current source for biasing the operational amplifier; and
an auxiliary transistor coupled in parallel to the current source for providing an additional current so as to stabilize the control signal in a short time.

11. The sensing amplifier of claim 1, wherein the operational amplifier comprises:
two transistors forming a differential input pair; and
two transistors coupled to the differential input pair for forming active loads;
wherein the current source is coupled to the differential input pair for biasing the differential input pair.

12. The sensing amplifier of claim 11, wherein a first end of the differential input pair is coupled to the voltage generator and a second end of the differential input pair is coupled to a memory cell.

13. The sensing amplifier of claim 11, wherein two transistors forming a differential input pair and the auxiliary transistor are P-type MOS transistors.

14. The sensing amplifier of claim 13, wherein two transistors forming active loads are N-type MOS transistors.

15. The sensing amplifier of claim 11, wherein two transistors forming a differential input pair and the auxiliary transistor are N-type MOS transistors.

16. The sensing amplifier of claim 15, wherein two transistors forming active loads are P-type MOS transistors.

17. The sensing amplifier of claim 10, wherein the operational amplifier adjusts the control signal according to the constant voltage.
